(19) United States
(12) Patent Application Publication
(10) Pub. No.: US 2024/0413239 A1
(43) Pub. Date: Dec. 12, 2024

(54) LDMOS NANOSHEET TRANSISTOR

(71) Applicant: Texas Instruments Incorporated, Dallas, TX (US)

(72) Inventors: Henry Litzmann Edwards, Garland, TX (US); Daniel Pham, Celina, TX (US); Sujatha Sampath, Salt Lake City, UT (US); Ali Saadat, Santa Clara, CA (US); Orlando Lazaro, Cary, NC (US); Vijay K. Reddy, Plano, TX (US); Steven Kummerl, Carrollton, TX (US)

(21) Appl. No.: 18/525,638

(22) Filed: Nov. 30, 2023

Related U.S. Application Data
(60) Provisional application No. 63/507,277, filed on Jun. 9, 2023.

(51) Int. Cl. H01L 29/78; H01L 29/06; H01L 29/08; H01L 29/10; H01L 29/66

(52) U.S. Cl. CPC H01L 29/7813; H01L 29/0665; H01L 29/0865; H01L 29/0882; H01L 29/1095; H01L 29/66068; H01L 29/66795

(57) ABSTRACT

Disclosed examples include microelectronic devices, e.g. Integrated circuits. One example includes a microelectronic device including a nanosheet lateral drain extended metal oxide semiconductor (LDMOS) transistor with source and drain regions having a first conductivity type extending into a semiconductor substrate having an opposite second conductivity type. A superlattice of alternating layers of nanosheets of a channel region and layers of gate conductor are separated by a gate dielectric, the superlattice extending between the source region and the drain region. A drain drift region of the first conductivity type extends under the drain region and a body region of the second type extends around the source region.

### CROSS-REFERENCE TO RELATED APPLICATIONS

This application claims the benefit of priority under 35 U.S.C. § 119(e) of U.S. Provisional Application No. 63/507,277, filed Jun. 9, 2023, which is hereby incorporated by reference in its entirety.

### TECHNICAL FIELD

This disclosure relates to the field of microelectronic devices. More particularly, but not exclusively, this disclosure relates to gated devices such as LDMOS transistors and in particular nanosheet LDMOS transistors.

### BACKGROUND

Semiconductor components are being continually improved to reliably operate with smaller feature sizes. Fabricating semiconductor devices that have increasingly higher performance while meeting performance and reliability specifications presents diverse challenges.

### SUMMARY

This summary is provided to introduce a brief overview of disclosed concepts in a simplified form that are further described below in the detailed description including the drawings provided. This summary is not intended to limit the scope of the disclosure or the claims.

Disclosed examples include microelectronic devices, e.g. Integrated circuits. One example includes a microelectronic device including a nanosheet laterally diffused metal oxide semiconductor (LDMOS) transistor with source and drain regions having a first conductivity type extending into a superlattice of alternating layers of semiconducting nanosheets. A superlattice of alternating layers of nanosheets of a channel region and layers of gate conductor are separated by a gate dielectric and extend between the source region and the drain region. A drain drift region of the first conductivity type extends under the drain region and a body region of the second type extends around the source region.

Another example provides an example structure of a nanosheet resistor having a plurality of superlattice structures of alternating layers of a nanosheets of a channel region between a plurality of highly doped regions in a substrate, the nanosheets and highly doped regions being electrically in series between a first terminal and a second terminal.

Another example provides an example structure of a nanosheet metal oxide semiconductor capacitor (MOSCAP) having a plurality of a superlattice structures of nanosheets of a channel region connected to one terminal and plurality of gate conductors connected to a second terminal, the nanosheets and the gate conductor being separated by a gate dielectric to form the nanosheet MOSCAP.

Other examples provide example structures of a nanosheet n-type metal oxide semiconductor (NMOS) transistor and a nanosheet p-type metal oxide semiconductor (PMOS) transistor having a superlattice of alternating layers of a nanosheets of a channel region and a gate conductor separated by a gate dielectric extending between the source region and the drain region.

### BRIEF DESCRIPTION OF THE VIEWS OF THE DRAWINGS

FIG. 1A through FIG. 1AG are cross sections of an example microelectronic device including a nanosheet LDMOS transistor in various stages of formation.

FIG. 2A and FIG. 2B are a cross sections of an example microelectronic device including a nanosheet NMOS transistor after formation.

FIG. 3A and FIG. 3B are a cross sections of an example microelectronic device including a nanosheet PMOS transistor after formation.

FIG. 4 is a cross section of an example microelectronic device including a nanosheet resistor after formation.

FIG. 5 is a cross section of an example microelectronic device including a nanosheet MOSCAP after formation.

FIG. 6 is a graph of Rsp vs. BVDSS comparing the effect of an increasing number of nanosheets in a nanosheet LDMOS transistor to the Rsp vs. BVDSS of a traditional LDMOS transistor.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events unless otherwise stated. Furthermore, some of the illustrated acts or events may be omitted in some examples in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” as used herein, may refer to ±5% to ±10% variations of the recited values in some cases. In other cases, the term “approximately” may refer to ±10% to ±20% variations of the recited values. Microelectronic devices are being continually improved to reliably operate with higher performance and smaller feature sizes.

Fabricating such microelectronic devices satisfying area scaling and reliability specifications presents ongoing challenges. Some gate-controlled devices such as metal-oxide-semiconductor (MOS) transistors include features for supporting high voltage operations, e.g. With a voltage applied to the drain (or drain structure) of 20 V, 30 V, 40 V, or even greater. Such MOS transistors may include drain diffusion profiles (or drain junction profiles) devised to support the high voltages applied to the drain, e.g. Having an extended portion to distribute the voltage drop across greater distances. Accordingly, such MOS transistors may be referred to as extended drain (ED) MOS transistors, for example drain-extended n-channel MOS (DENMOS) transistors, drain-extended p-channel MOS (DEPMOS) transistors, laterally-diffused MOS (LDMOS) transistors, as well as groups of DENMOS and DEPMOS transistors (which may be referred to as complimentary drain-extended MOS or DECMOS transistors). Other gate controlled microelectronic devices may include a gated bipolar semiconductor device, a gated unipolar semiconductor device, an insulated gate bipolar transistor (IGBT), a metal oxide semiconductor (MOS)-triggered SCR, a MOS-controlled thyristor, and a gated diode ED transistors are scaled down to smaller sizes to reduce microchip cost and improve circuit performance by reducing parasitic resistance and capacitance, it can be challenging to maintain good reliability and yield, so it may be advantageous to improve transistor performance independently of lateral lithographic scaling.

Stacking transistor channels in three dimensions may be advantageous by reducing on-resistance and increasing on-current proportionally to the number of layers stacked. An example ED transistor as described in FIB. 1A-1AG may have a nanosheet region doping profile whose dose lies in the resurf range 10¹²-10¹³ cm⁻², which sets the drain drift region contribution to source-drain on resistance (RDSON), which often is the dominant contribution. Therefore, stacking multiple nanosheet ED transistors in parallel in three dimensions drain enables the reduction of RDSON in a given area, so that the cost figure of merit specific on resistance (RSP) with is equal to the RDSON times the area is reduced and power technology scaling can be improved for a given lithographic scaling capability. The physical geometry of the nanosheets for ED transistor differ from those in nanosheet digital CMOS transistors. In general, nanosheet digital CMOS transistors use nanosheet architecture including nanosheet layers just a few nanometers thick. For high voltage ED transistors, however, drain drift region mobility may be beneficial, and nanosheets thicker than 10 nm, with increasing thicknesses from 20 nm to 500 nm or greater, may be used to achieve target RSP values for efficient power circuit design. In some examples, the nanosheet thickness could be 50 nm to 500 nm, or such as 100 nm to 300 nm, which may keep the drain drift region doping concentration low enough to preserve high electron mobility, hence low RSP.

The disclosure includes several example of microelectronic devices including a nanosheet LDMOS transistor as well as several other nanosheet microelectronic devices. While such examples and variations may be expected to provide lower RDSON than some baseline devices of similar size and otherwise similar performance characteristics, no particular result is a requirement of the present disclosure unless explicitly recited in a particular claim. As used herein the term “superlattice” means a periodic structure of layers of at least two different materials. A superlattice may have many such layers, and in some cases may have as few as three layers including a layer of a first material between two layers of a second material. As used herein the term “nanosheet” means a layer within a superlattice and having a thickness (in a direction normal to surface of the major surface of a substrate over which the superlattice is formed) no greater than 500 nm. A nanosheet may also be an active layer of a semiconductor device including the nanosheet.

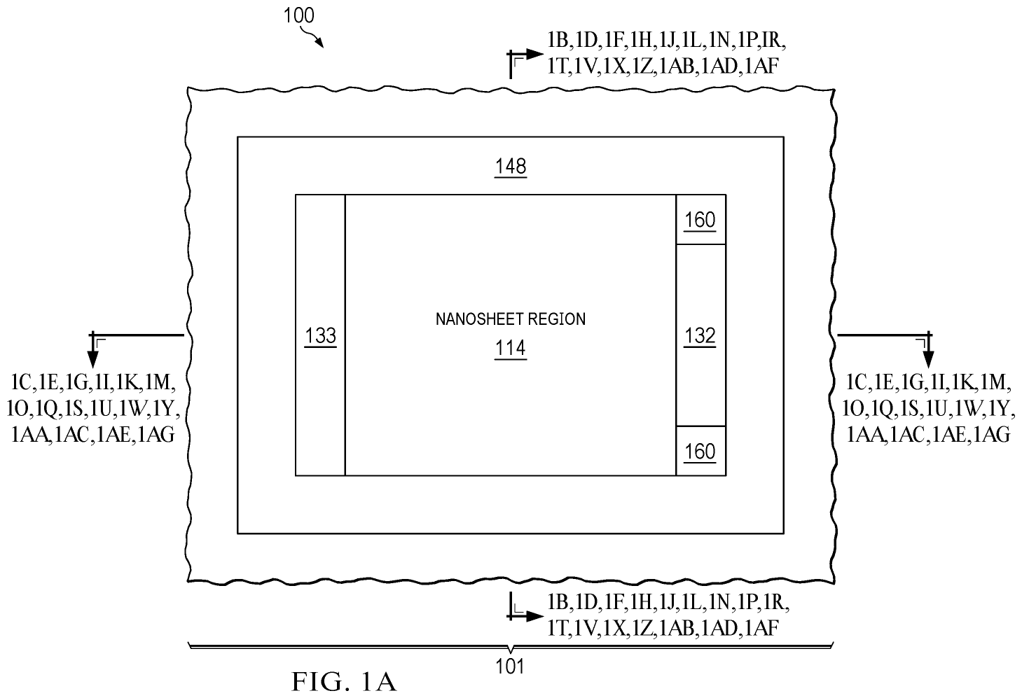

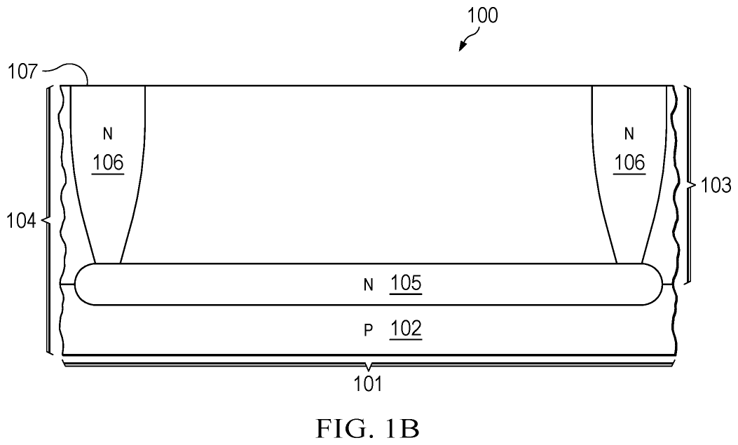

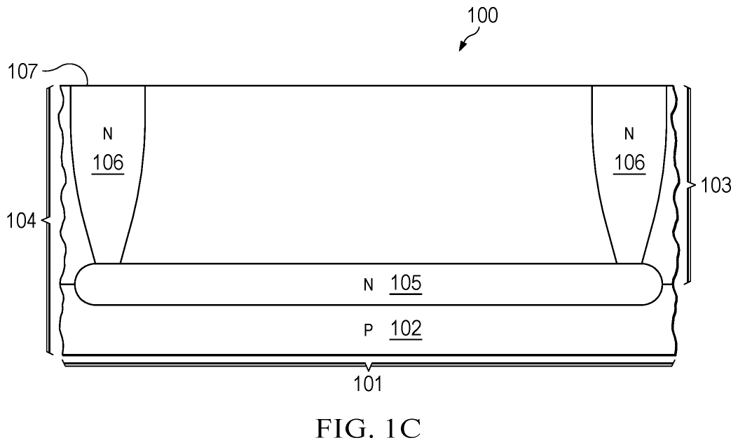

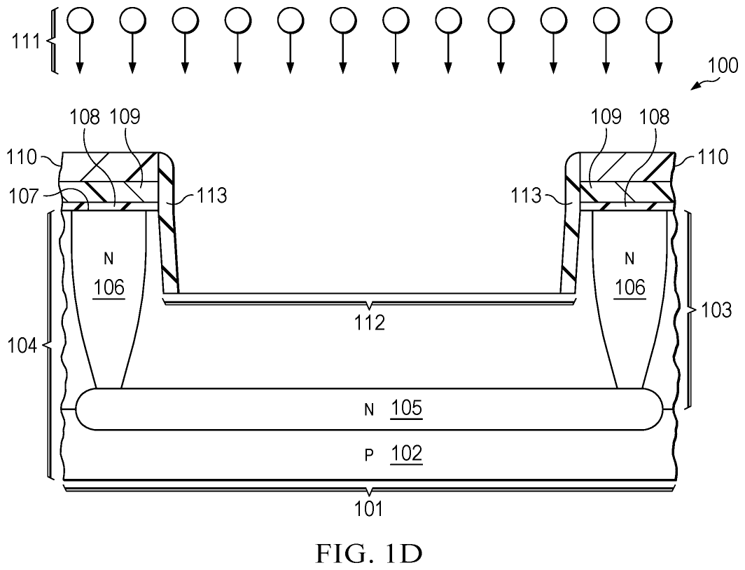

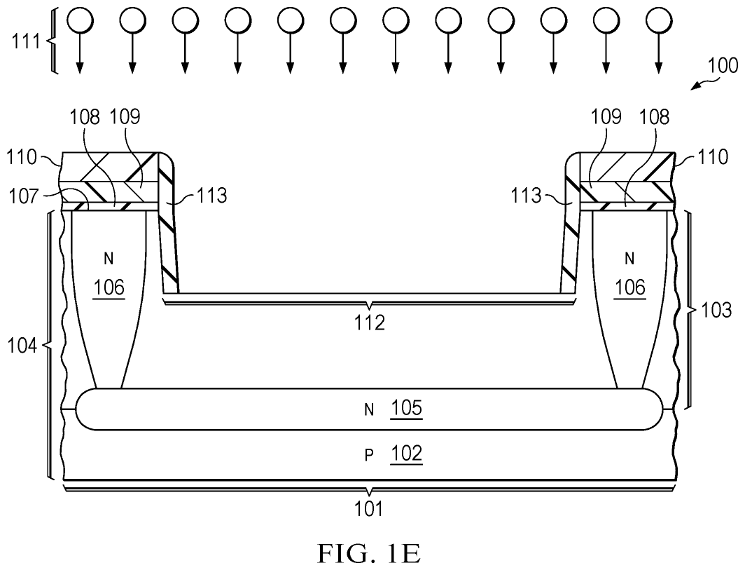

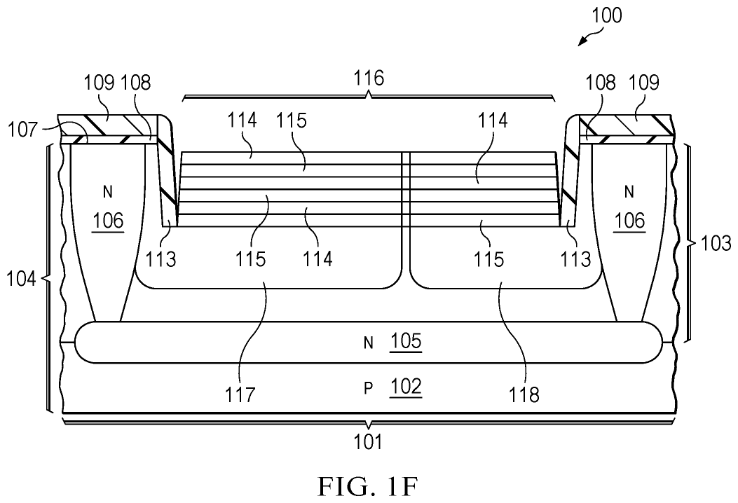

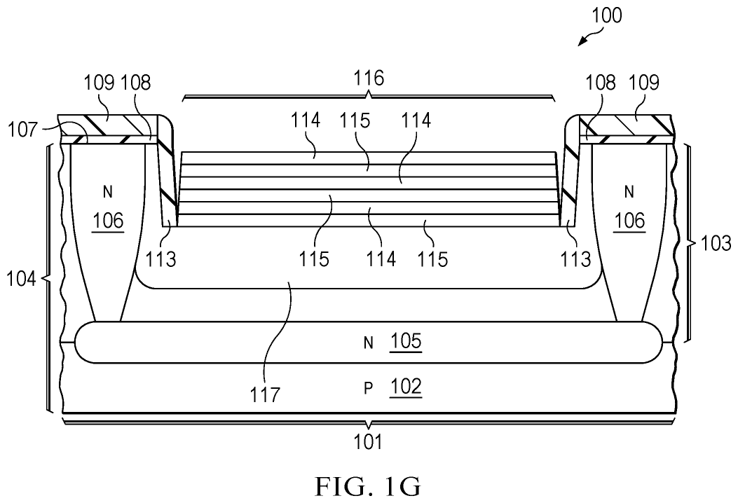

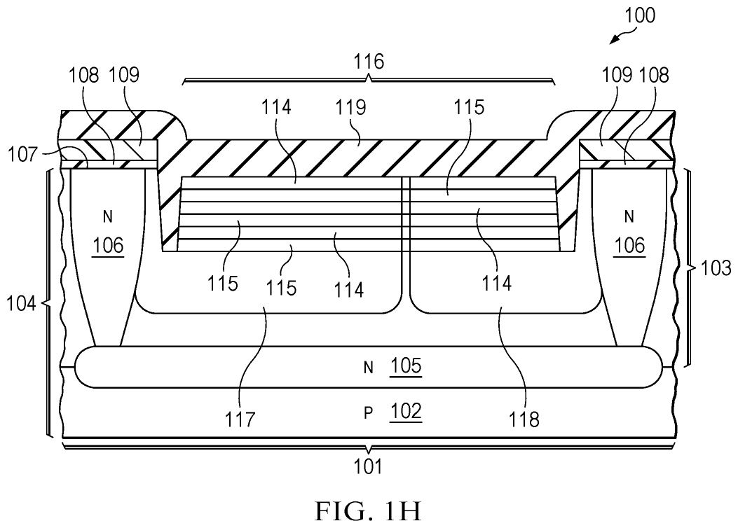

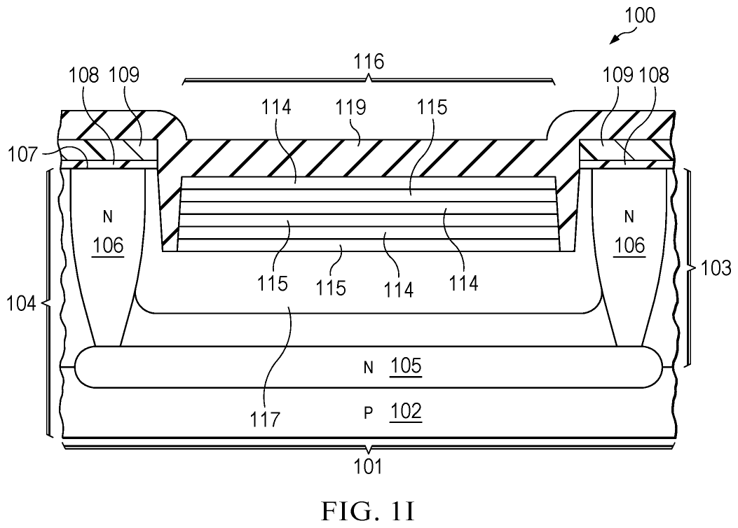

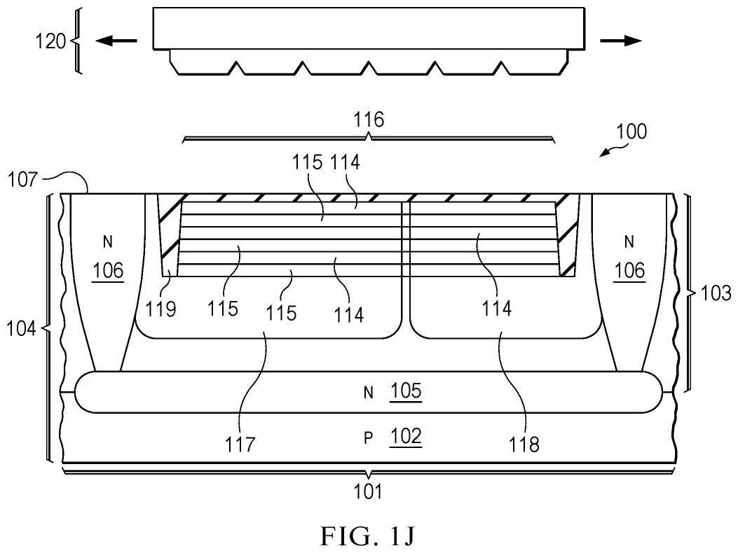

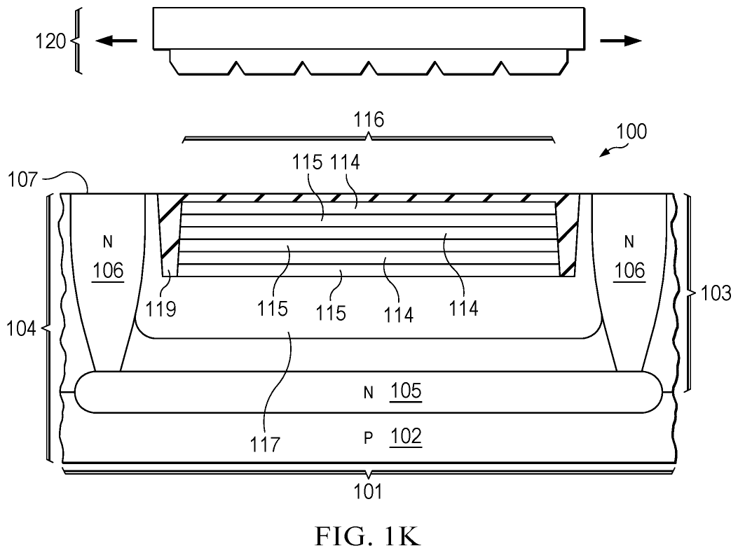

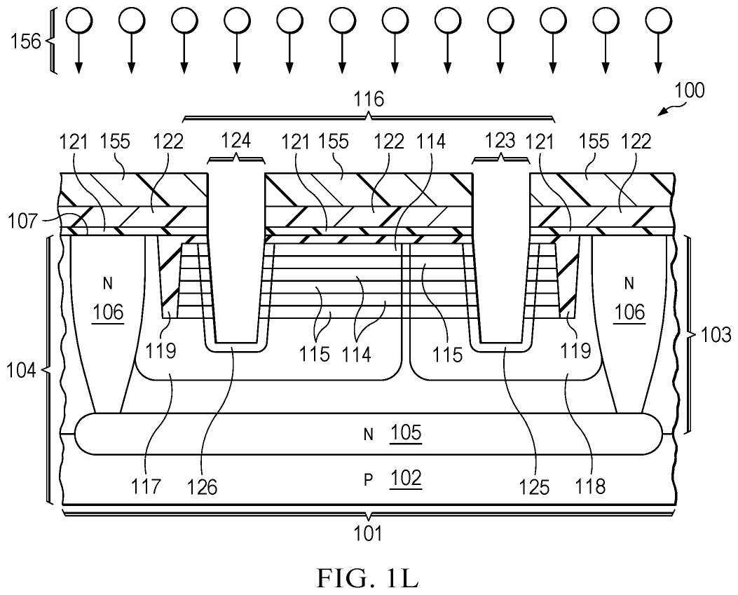

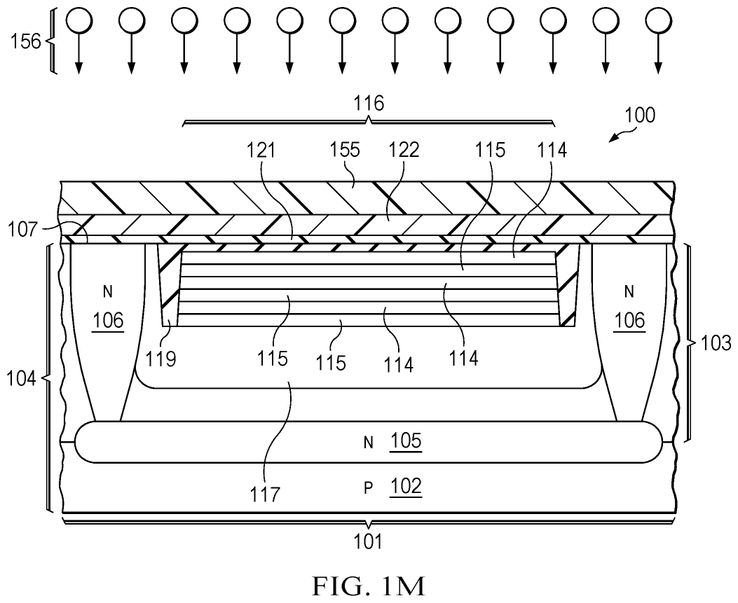

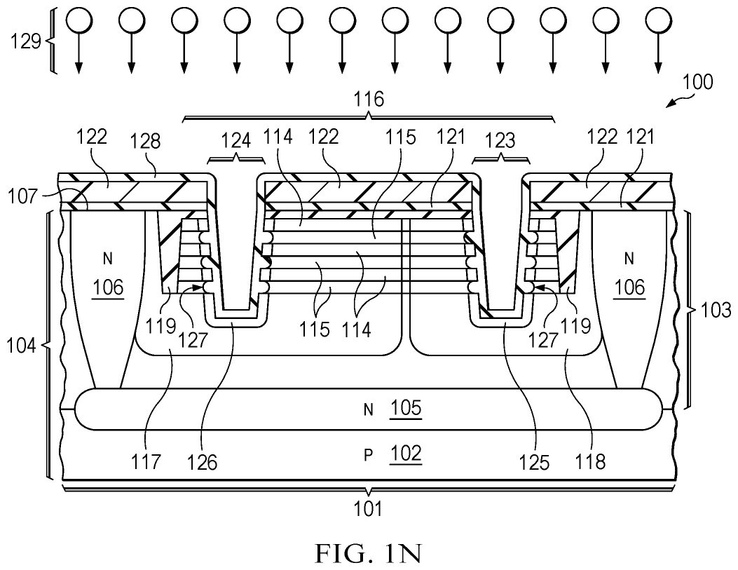

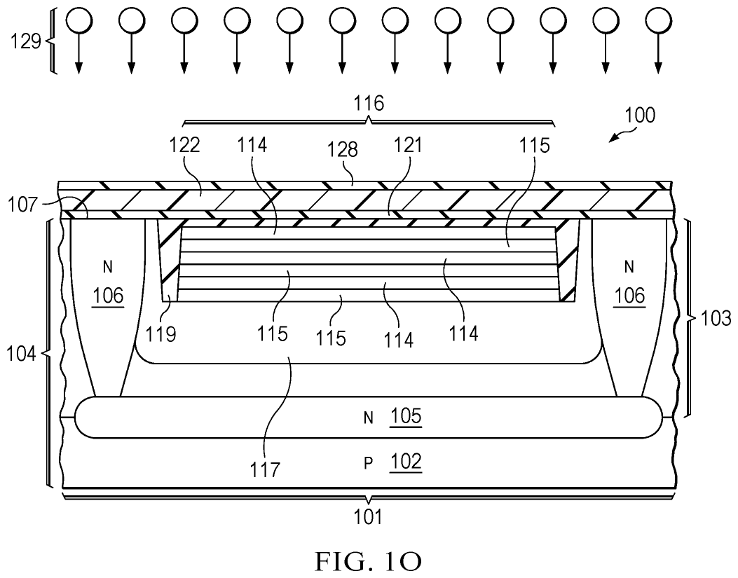

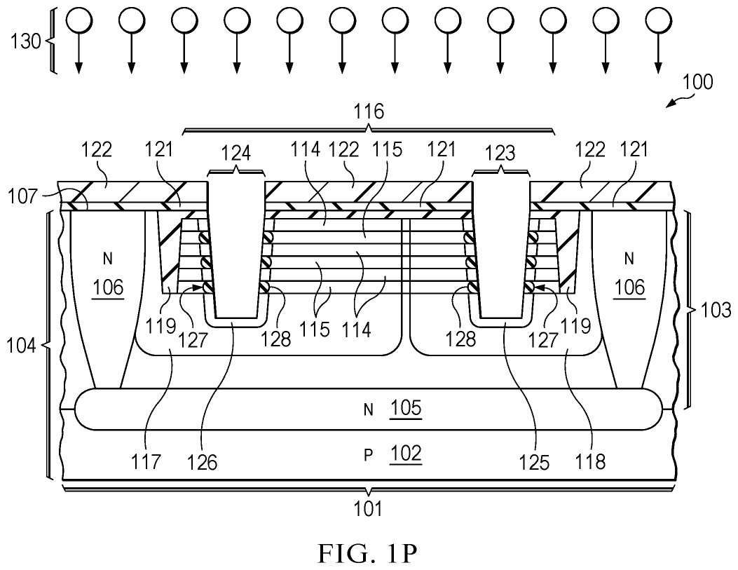

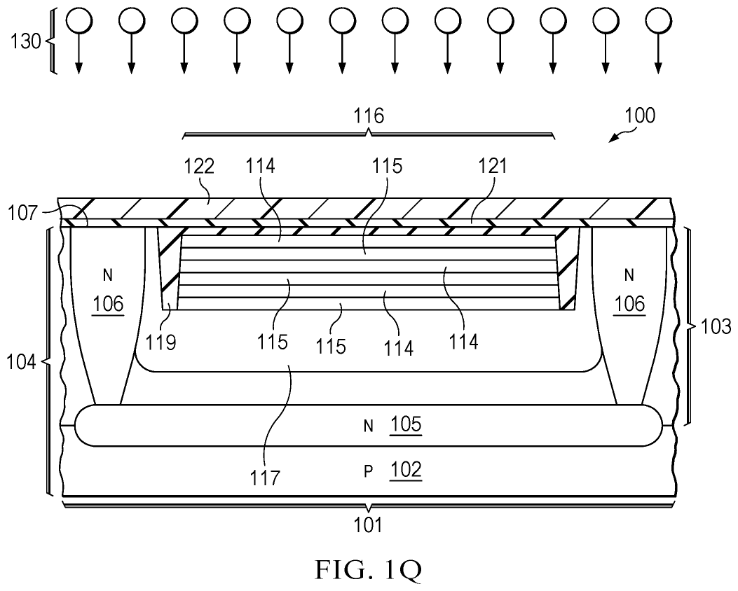

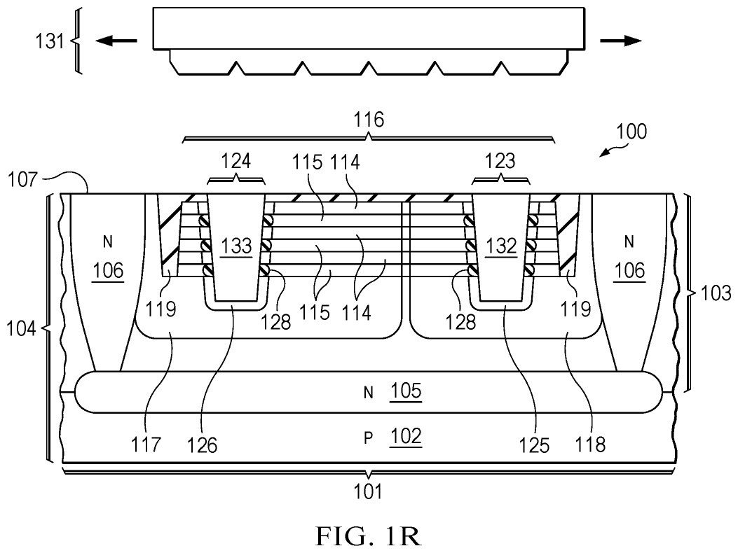

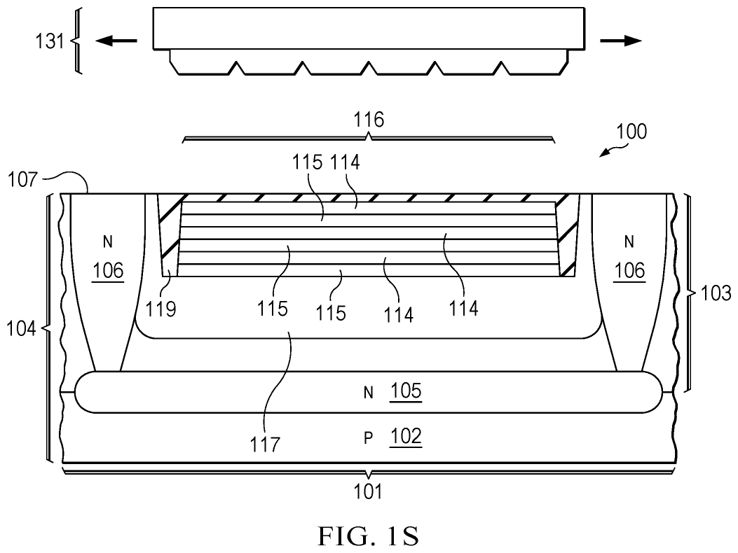

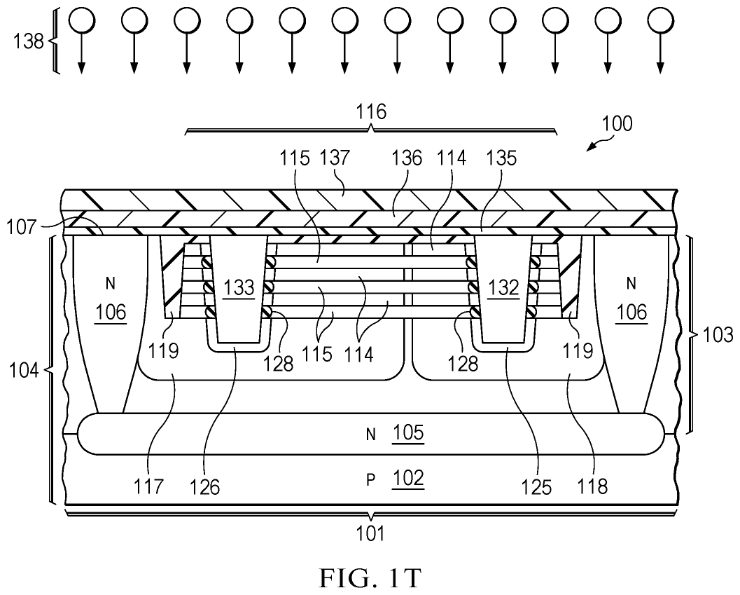

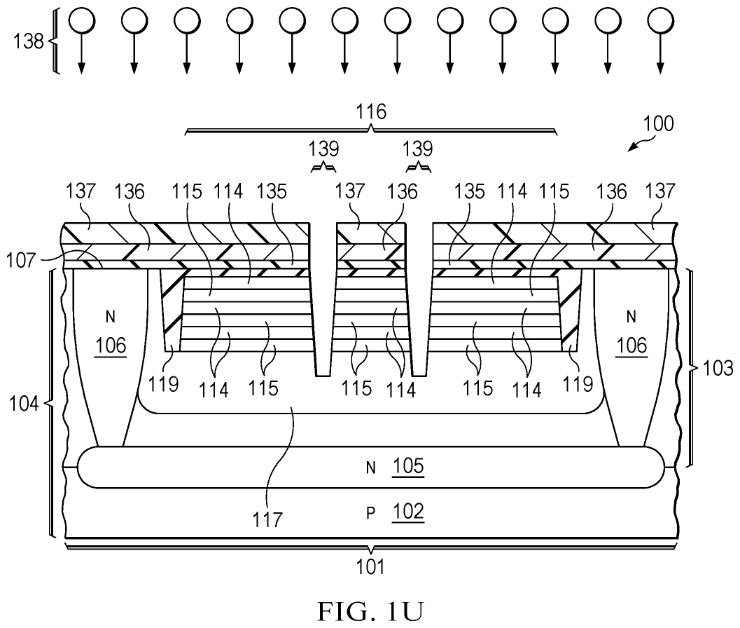

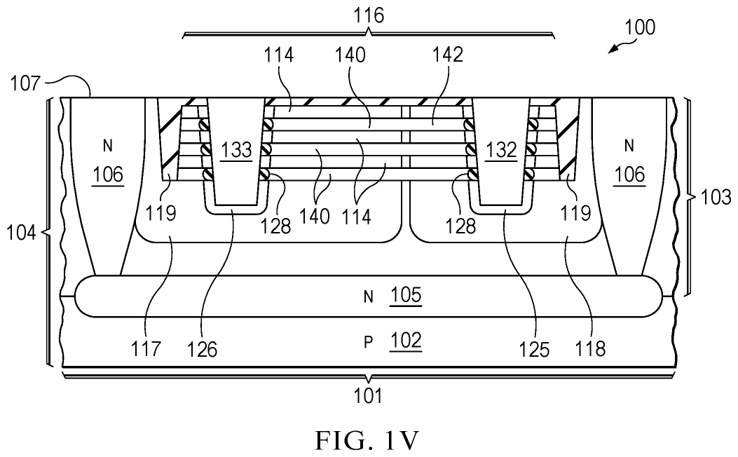

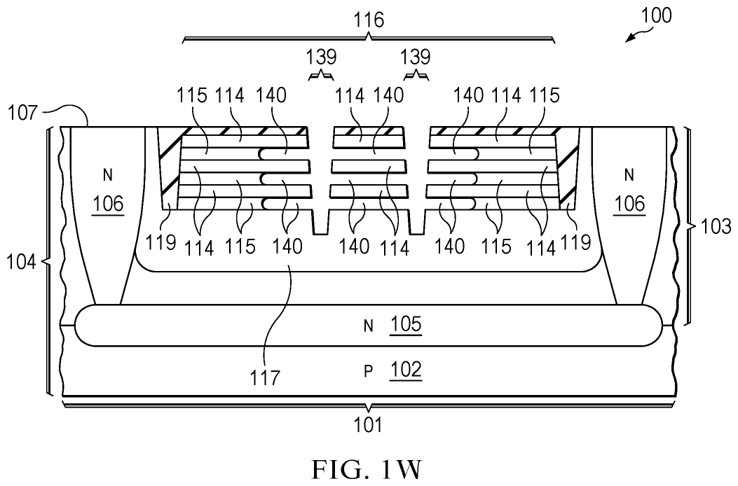

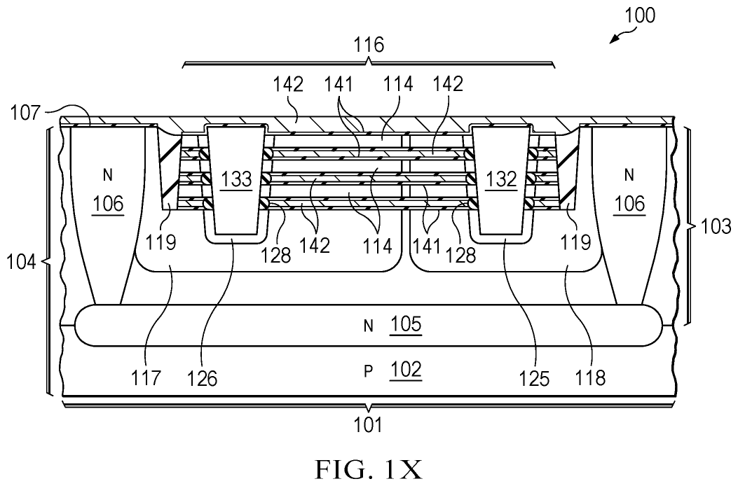

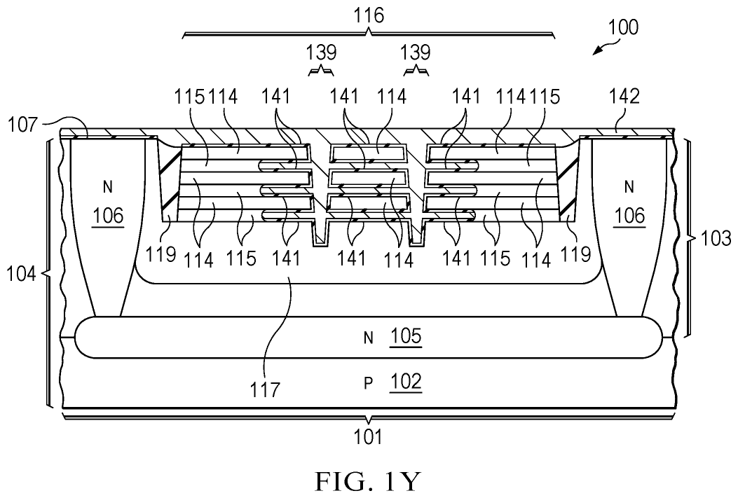

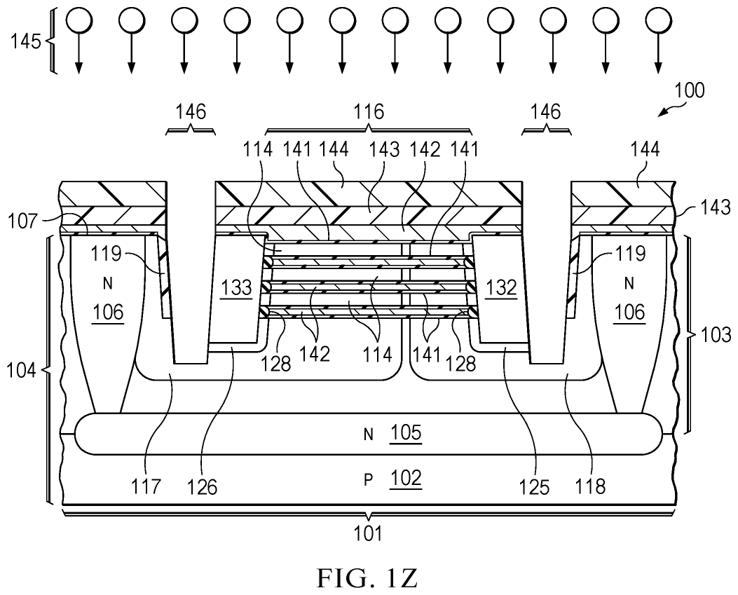

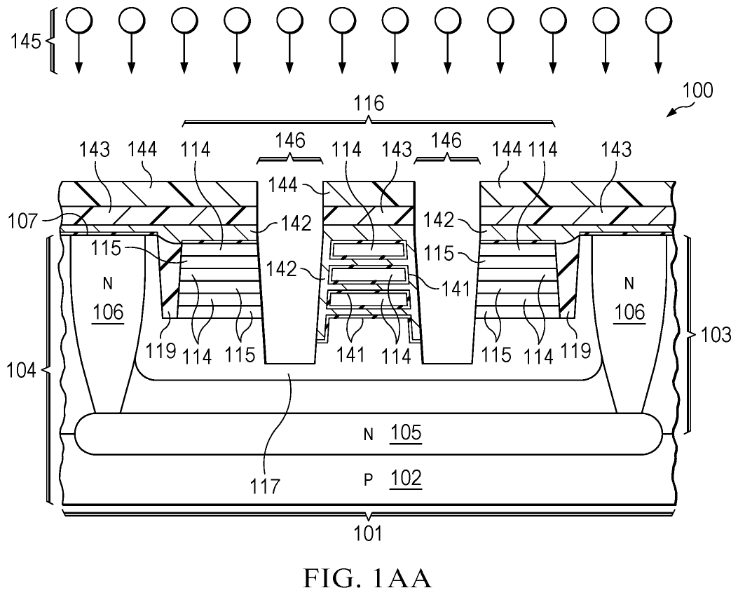

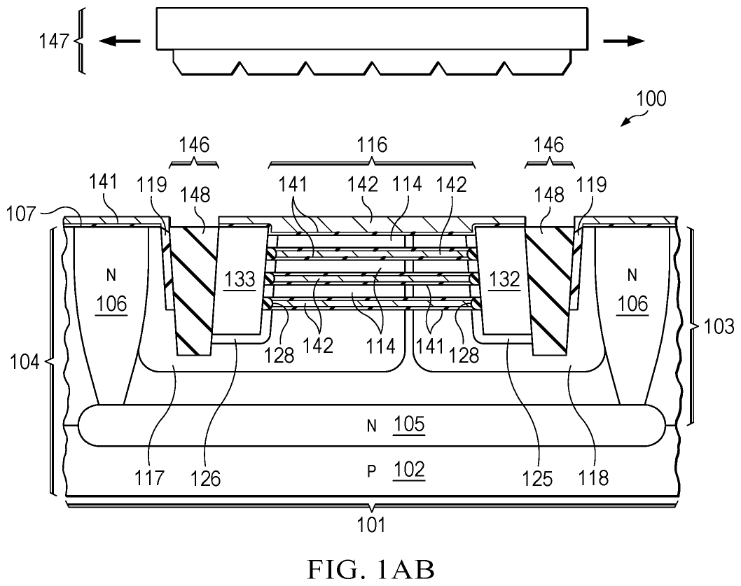

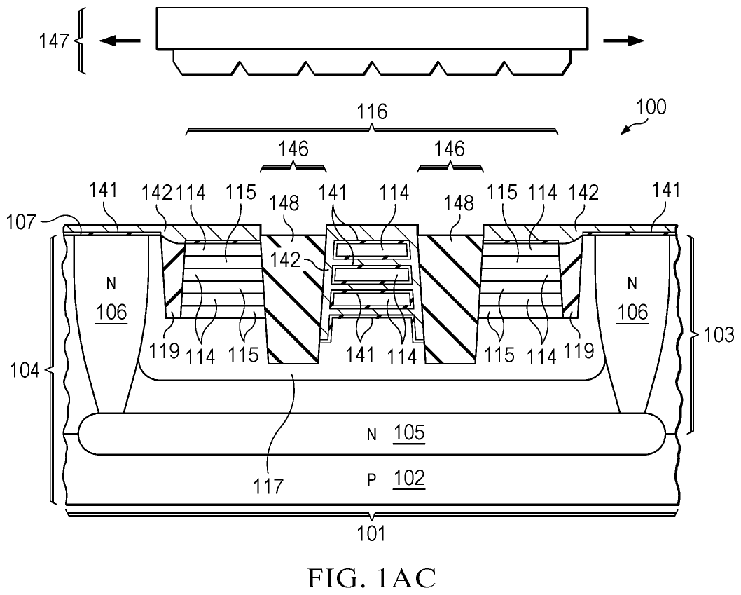

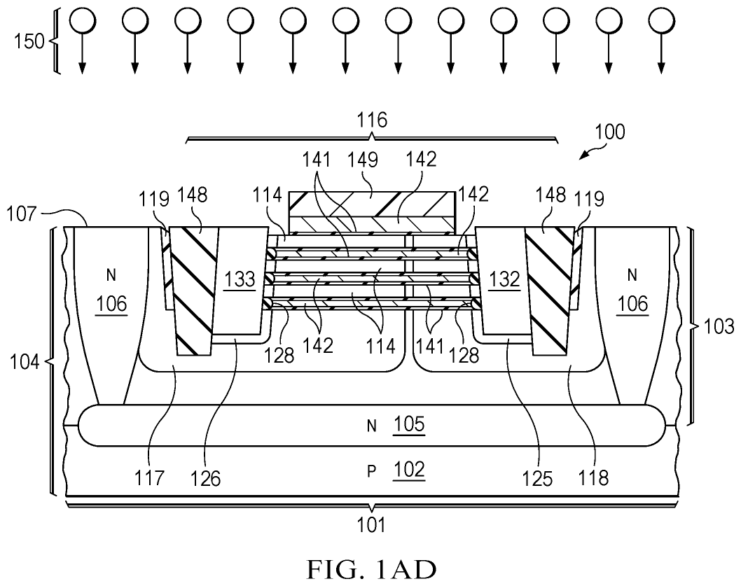

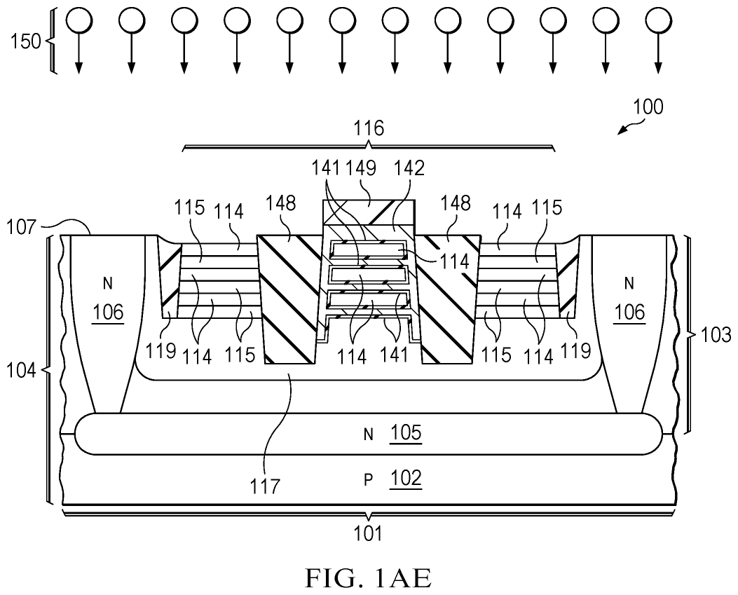

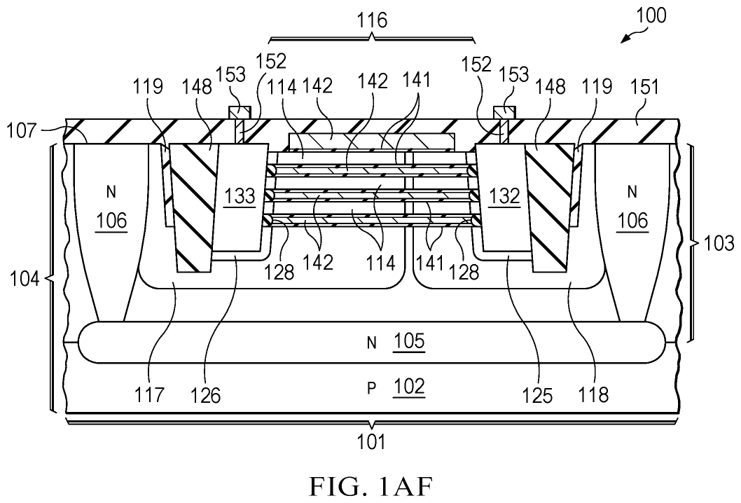

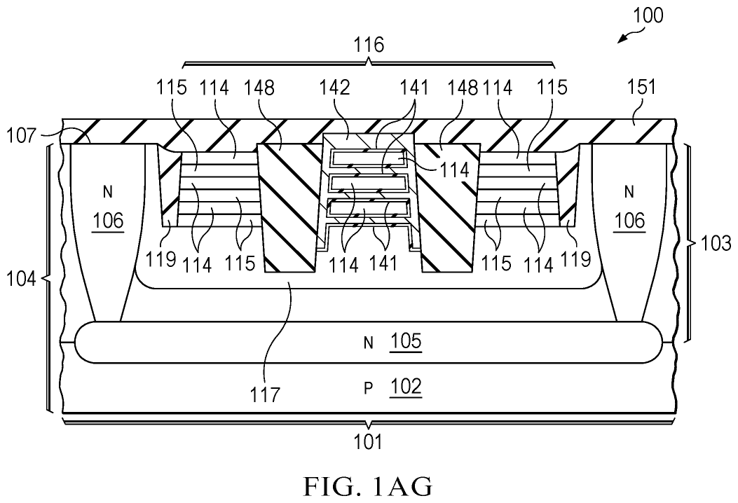

FIG. 1A through FIG. 1AG are representative of a first type of microelectronic device 100 to which the principles of the disclosure may be beneficially applied. FIGS. 1B-1AG figures show cross sections of an example microelectronic device 100, e.g. A nanosheet LDMOS transistor 101, herein referred to as a nanosheet transistor 101, in successive stages of formation. Without implied limitation, a nanosheet region 116 in this example includes nanosheet layers 114 described below that are implemented in an n-type laterally diffused metal oxide semiconductor (n-type LDMOS) nanosheet transistor 101. Another implementation of a p-type LDMOS transistor that includes the nanosheet region 116 is a p-type LDMOS transistor that is within the scope of this example. In the example n-type nanosheet transistor 101, dopants of a first conductivity type are n-type dopants and dopants of a second conductivity type are p-type dopants. Additional implementations of the nanosheet layers 114 are not limited to, but may include in a nanosheet NMOS transistor 201, a nanosheet PMOS transistor 301, a nanosheet resistor 401, and a nanosheet MOSCAP 501. Examples are described herein with silicon as the semiconductor material for the nanosheet layers 114 and SiGe as a sacrificial material initially present between the nanosheet layers 114. Other examples within the scope of the disclosure may use other combinations of semiconductor and sacrificial materials. For example, the roles of silicon and SiGe may be reversed such that SiGe is used as the semiconductor material of the nanosheet layers 114 and silicon is used as the sacrificial material. Other combinations may also be used, where the materials may be formed in thi, alternating layers, and one layer may be preferentially removed leaving intact semiconductor nanosheet layers.

FIG. 1A shows a top-down representation of the microelectronic device 100 including nanosheet transistor 101 after formation. The top-down view shows a shallow trench isolation (STI) region 148 which is the outermost component of the nanosheet transistor 101. Nanosheet layers 114 are between a source region 132 and a drain region 133. A p-type back gate region 160 is conductively connected to the source region 132. For clarity, at successive stages of formation where figures are provided, a figure is provided showing a cross section along the axis through the source region 132, the nanosheet region 116, and the drain region 133, with a companion cross section at the same successive stage of formation in a perpendicular manner across the nanosheet region 116. While FIG. 1A shows a single source region 132, a single drain region 133, and a single nanosheet region 116, (cross section in FIG. 1AF) multiple source regions 132 and drain regions 133 may be added to increase the number of nanosheet channels. Likewise, multiple nanosheet regions 116 may be used for increased parallel conduction.

Referring to FIG. 1B and FIG. 1C, the microelectronic device 100 including a nanosheet transistor 101 is formed in and on a base wafer 102, such as a silicon wafer. The base wafer 102 may have a second conductivity type, which may be p-type in this example, as indicated in FIG. 1B and FIG. 1C. In an alternate version of this example, the base wafer 102 may include a dielectric material, such as silicon dioxide or sapphire, to provide a silicon-on-insulator substrate. A semiconductor material 103 is formed on the base wafer 102. The semiconductor material 103 includes primarily silicon, and may consist essentially of silicon and dopants, such as boron, and may have the second conductivity type, that is, p-type. The semiconductor material 103 may be formed by an epitaxial process and may be 5 microns to 15 microns by way of example. The semiconductor material 103 extends to a top surface 107. The base wafer 102 and the semiconductor material 103 form the substrate 104.

A buried layer 105 may be formed in the substrate 104, extending into both the base wafer 102 and the semiconductor material 103. The buried layer 105 has a first conductivity type, opposite from the second conductivity type. In this example, the first conductivity type is n-type. The buried layer 105 may be formed by implanting dopants of the first conductivity type, such as phosphorus, arsenic, or antimony, into the base wafer 102 before the semiconductor material 103 is formed. The base wafer 102 may be annealed prior to forming the semiconductor material 103, and the semiconductor material 103 may subsequently be formed by an epitaxial process of thermal decomposition of silane, during which the dopants of the first conductivity type diffuse deeper into the base wafer 102 and into the semiconductor material 103, forming the buried layer 105.

A deep well 106 may be formed in the semiconductor material 103, extending from the top surface 107 of the substrate 104 to the buried layer 105. The deep well 106 may have the first conductivity type, n-type in this example. The deep well 106 may be formed by implanting dopants of the first conductivity type, such as phosphorus, into the semiconductor material 103, followed by a thermal drive to diffuse the implanted dopants to the buried layer 105 and activate the implanted dopants. The deep well 106 may have an average concentration of the dopants of the first conductivity type that is at least 2 to 10 times greater than an average concentration of dopants of the second conductivity type in the semiconductor material 103 outside of the deep well 106. The deep well 106 provides isolation between the nanosheet transistor 101 and other components of the microelectronic device 100. The deep well 106 may preferably be degenerately doped to provide low leakage between the nanosheet transistor 101 and other components of the microelectronic device 100.

Referring to FIG. 1D and FIG. 1E, cross sections are shown after a nanosheet superlattice trench 112 has been formed. After formation of the buried layer 105 and the deep well 106, first pad oxide layer 108 may be formed on the top surface 107 of the substrate 104. The first pad oxide layer 108 may include primarily silicon dioxide, may be formed by a thermal oxidation process or a thermal chemical vapor deposition (CVD) process, and may have a thickness of 5 nanometers to 200 nanometers, by way of example. A first hard mask layer 109 may be formed on the first pad oxide layer 108. The first hard mask layer 109 may include a layer of a material composed primarily of silicon nitride, and a layer of a material containing primarily silicon dioxide. The first hard mask layer 109 may have a thickness of 50 nanometers to 3 microns, depending on a depth of nanosheet superlattice trench 112. The first pad oxide layer 108 may provide stress relief between the semiconductor material 103 and the first hard mask layer 109. The silicon nitride portion of the first hard mask layer 109 may provide a stop layer for subsequent etch and planarization processes. The silicon dioxide layer of the first hard mask layer 109 may provide a hard mask during a superlattice trench etch 111 to form the nanosheet superlattice trench 112. A superlattice trench photomask 110 may be formed on the first hard mask layer 109 with openings which expose the first hard mask layer 109 in areas for the nanosheet superlattice trench 112.

A superlattice trench etch 111 forms the nanosheet superlattice trench 112 in the substrate 104. The superlattice trench etch 111 may include multiple steps. After the superlattice trench etch 111, the superlattice trench photomask 110 is removed. A superlattice trench dielectric sidewall 113 is formed after the superlattice trench photomask 110 is removed. The superlattice trench dielectric sidewall 113 is formed by depositing a blanket layer of a dielectric such as silicon dioxide or silicon nitride followed by an anisotropic etch (neither process specifically shown). The anisotropic etch leaves a superlattice trench dielectric sidewall 113 which prevents deposition of silicon or silicon-germanium during the nanosheet region 116 formation process. After the formation of the superlattice trench dielectric sidewall, the horizontal surface of the nanosheet superlattice trench 112 is free of dielectric material.

Referring to FIG. 1F and FIG. 1G, cross sections are shown after a nanosheet region 116, a drain drift region 117 and the p-type well region 118 have been formed. Not explicitly shown in these views, the p-type well region connects to the back gate region 160. The nanosheet region 116 may be formed by epitaxial deposition or atomic-layer deposition (ALD) to produce alternating layers of a silicon-germanium alloy herein referred to as silicon-germanium layers 115 and unalloyed silicon nanosheet layers 114. The nanosheet layers 114 may have a thickness in a range between about 10 nm and about 200 nm, though other thicknesses are contemplated. The silicon-germanium layers 115 are a sacrificial layer and are etched away during subsequent processing. While the sacrificial layer in the nanosheet transistor 101 may be a silicon-germanium layer 115, other semiconductor materials which may be selectively etched in a superlattice stack containing nanosheet layers 114 may be used as the sacrificial layer. Dielectric materials such as silicon dioxide and silicon nitride which may be selectively etched in a superlattice stack containing nanosheet layers 114 may also be used as a sacrificial layer.

The drain drift region 117 is formed in the substrate 104, in the semiconductor material 103, a portion of the nanosheet region 116, and will subsequently surround the drain region 133 referred to in FIG. 1R. One or more n-type implants are performed to form the drain drift region 117 (which may be referred to as an n-drift region) in the substrate 104. The n-type dopant that defines the n-drift region 117 may be implanted in one step or in multiple steps. For example, phosphorus may be implanted with a dose such that each of the nanosheet layers 114 receives a dose of near 1×10¹² cm⁻² and 1×10¹³ cm⁻² with energies suitable for forming the n-drift region 117 with or without subsequent thermal cycles. Arsenic may also be implanted with a similar dose with an energy relatively higher than the phosphorus implant. The n-drift region 117 has an average doping concentration less than the average doping concentration of the drain region 133.

A p-type well region 118 is formed in the substrate 104 in the semiconductor material 103 and a portion of the nanosheet region 116, and will subsequently surround the source region 132 referred to in FIG. 1R. One or more p-type implants are performed to form the p-type well region 118 (which may be referred to as an p-well region) in the substrate 104. The p-type dopant that defines the p-type well region 118 may be implanted in one step or in multiple steps. For example, boron may be implanted at a total dose of between 1×10¹² cm⁻² and 1×10¹³ cm⁻² with energies suitable for forming the p-type well region 118 with or without subsequent thermal cycles. The p-type well region 118 may also receive a heavier implanted dose which does not deplete under reverse bias and is heavy enough to suppress source/drain leakage in the off state. Additionally, the p-type well region 118 doping may be too heavy for use in a p-type nanosheet LDMOS transistor (not specifically shown), if so, p-type drift implant may be required.

Referring to FIG. 1H and FIG. 1I, cross sections are shown after a dielectric layer 119 is deposited. The dielectric layer 119 forms a dielectric gap fill between the nanosheet region 116 and the substrate 104.

Referring to FIG. 1J and FIG. 1K, cross sections are shown after a chemical mechanical polish (CMP) process 120 has removed the dielectric layer 119 outside the superlattice sidewall trenches. The dielectric layer 119 acts as a gap fill between the nanosheet region 116 and the substrate 104. After the CMP process 120, the first hard mask layer 109 is removed.

Referring to FIG. 1L and FIG. 1M, cross sections are shown after a source/drain trench etch 156 forms a source trench 123 and a drain trench 124. A second pad oxide layer 121 and a second hard mask layer 122 are first formed followed by a source/drain photolithographic pattern 155. After the formation of the source/drain photolithographic pattern 155, a multi-step etch process is used to etch the second hard mask layer 122, the second pad oxide layer 121, and the nanosheet region 116 in the open areas of the source/drain photolithographic pattern 155. After the source trench 123 and the drain trench 124 are formed, a p-body photolithographic pattern is formed (not specifically shown) and an angled implant (not specifically shown) is used to implant p-type dopants in the region surrounding the source trench 123 to form a p-type body region 125. After the p-type body region 125 is formed, the p-body photolithographic pattern is removed and a n-buffer photolithographic pattern is formed (not specifically shown) and an angled implant (not specifically shown) of a n-type dopant is used to implant n-type dopants in the region surrounding the drain trench 124 to form a n-type buffer region 126. After the formation of the n-type buffer region 126, the n-type buffer photolithographic pattern is removed. Alternatively plasma doping may be used in some circumstances to implant dopants and form the p-type body region 125 and the n-type buffer region 126.

Referring to FIG. 1N and FIG. 1O, cross sections are shown after an inner spacer dielectric 128 has been deposited. After the formation of the p-type body region 125, and the n-type buffer region 126 are formed, an isotropic SiGe etch, either a plasma etch or a wet etch selective to the silicon-germanium layers 115 (not specifically shown) is used to remove a portion of the silicon-germanium layers 115, forming an inner spacer recess 127 near the sidewalls of the p-type body region 125 and the n-type buffer region 126. After the inner spacer recess 127 is formed, a conformal layer of an inner spacer dielectric 128 is formed. The inner spacer dielectric 128 is a conformal dielectric layer which fills the inner spacer recess 127.

Referring to FIG. 1P and FIG. 1Q, cross sections are shown after an inner spacer dielectric etch 130 The inner spacer dielectric etch 130 is an anisotropic etch which removes the inner spacer dielectric 128 from the top surface of the second hard mask layer 122, and regions inside the source trench 123 and the drain trench 124, with inner spacer dielectric 128 remaining in those regions where the SiGe etch recessed the sidewalls of the source trench 123 and the drain trench 124.

Referring to FIG. 1R and FIG. 1S cross sections are shown after a polysilicon CMP process 131 has completed the formation of a source region 132 and a drain region 133. After the formation of the inner spacer dielectric 128 discussed in FIGS. 1P and 1Q, a n-type polysilicon deposition (not specifically shown) fills the source trench 123 and the drain trench 124 with n-type polysilicon. The n-type silicon deposition to fill the source trench 123 and the drain trench 124 may also be an epitaxial deposition. A polysilicon trench CMP process 131 is used to remove polysilicon outside of source trench 123 and the drain trench 124. After the polysilicon trench CMP process 131, the second hard mask layer 122 and the second pad oxide layer 121 are removed. After the polysilicon CMP process is complete, processes similar to those shown in FIG. 1L through FIG. 1S may be repeated using a p-type in-situ polysilicon deposition to form p-type regions such as the p-type back gate region 160 (out of the plane of FIG. 1R and FIG. 1S but referred to in FIG. 1A). The p-type back gate region 160 is later conductively connected to the source region 132 either through contacts 152 and an interconnect 153, or through a common silicide connection (not specifically shown).

Referring to FIG. 1T and FIG. 1U cross sections are shown after a gate trench 139 is formed. After the formation of the source region 132 and drain region 133 referred to in FIG. 1R, a third pad oxide 135 and a third hard mask 136 are formed. A gate trench photolithographic mask 137 is patterned on the third hard mask 136. A multi-step gate trench etch 138 removes the third hard mask 136, the third pad oxide 135, and the nanosheet region 116 in regions exposed by the gate trench photolithographic mask 137 forming the gate trench 139. After the formation of the gate trench 139, the gate trench photolithographic mask 137, the third hard mask 136, and the third pad oxide 135 are removed.

Referring to FIG. 1V and FIG. 1W cross sections are shown after a plasma etch or a wet etch which selectively removes the silicon-germanium layers 115 of the nanosheet region 116 leaving superlattice voids 140 with adjacent nanosheet layers 114 remaining. The superlattice voids 140 leave the nanosheet layers 114 suspended over the substrate 104 by attachments to the source region 132 and the drain region 133. After removing the silicon-germanium layers 115 a cleanup process that includes supercritical CO₂ may be employed to remove residues.

Referring to FIG. 1X and FIG. 1Y, cross sections are shown after a silicon nanosheet gate dielectric layer 141 and a gate conductor 142 are formed. The silicon nanosheet gate dielectric layer 141, which may be formed by thermal oxidation of the nanosheet layers 114, forms a continuous sheath around each of the nanosheet layers 114 between the source region 132 and the drain region 133. The gate conductor 142 fills the superlattice voids 140, the gate trenches 139, and forms a continuous layer over the nanosheet region 116. By repeating the formation steps of FIG. 1T through FIG. 1Y and switching the n-type doped gate conductor 142 with a p-type gate conductor, gate conductors (not specifically shown) may be formed to support p-type nanosheet transistors.

Referring to FIG. 1Z and FIG. 1AA, cross sections are shown after an isolation trench etch 145 has formed an isolation trench 146. To form the isolation trench 146, a hard mask 143 is formed on the gate conductor 142. After formation of the hard mask 143, a photomask 144 is formed. The isolation trench etch 145 forms the isolation trench 146 in the open areas of the photomask 144 by etching portions of the hard mask 143, the gate conductor 142, the silicon nanosheet gate dielectric layer 141, and the nanosheet region 116. The isolation trench etch 145 also etches into, and stops in the semiconductor material 103. Specifically within the drain drift region 117 and the well region 118. After the isolation trench etch 145, the photomask 144 is removed. The hard mask 143 remains in place as an etch stop for a subsequent shallow trench isolation (STI) CMP process 147 referred to in FIG. 1AB and FIG. 1AC. The isolation trench etch 145 may also be used to create an array of nanosheet transistors (not specifically shown) by etching a plurality of trenches within a larger nanosheet transistor 101 that isolate a plurality of sub-transistors similar to the nanosheet transistor 101, each sub-transistor containing a separate source region 132, drain region 133, and nanosheet region 116.

FIG. 1AB and FIG. 1AC, cross sections are shown after the STI CMP process 147 has formed the STI region 148. The STI region 148 is formed by first forming a layer of a silicon dioxide or similar dielectric in the gate trench 146 and on the hard mask 143 (referred to in FIG. 1AA) of the nanosheet transistor 10. A high-density plasma (HDP) deposition or a high aspect ratio plasma (HARP) technique may be used to fill the gate trench 146 by way of example. A STI CMP process 147 may be used to remove the dielectric overburden outside the gate trench 146, leaving an STI region 148 in the gate trench 146. The STI region 148 isolates the nanosheet layers 114, the source region 132, and the drain region 133 from the remaining nanosheet region 116 between the STI region 148 and the dielectric layer 119. After the STI CMP process 147, the hard mask 143 referred to in FIG. 1Z and FIG. 1AA (not specifically shown in FIG. 1AB and FIG. 1AC), is removed using a phosphoric acid chemistry, and a HF based chemistry is used to achieve the specified final profile of the STI region 148.

FIG. 1AD and FIG. 1AE, cross sections are shown after a gate conductor plasma etch 150. A gate conductor photomask 149 is formed on the gate conductor 142. After the formation of the gate conductor photomask, a gate conductor plasma etch 150 removes the gate conductor 142 is the open areas of the gate conductor photomask 149. After the gate conductor plasma etch 150, the gate conductor photomask 149 is removed.

After the gate conductor photomask 149 is removed, sidewall spacers (not specifically shown) may be formed on the vertical surfaces of the gate conductor 142 and may extend 50 nm to 200 nm from the lateral edge of the gate conductor 142. The sidewall spacers may prevent subsequent silicide formation on the vertical surfaces of the gate conductor 142 and on a portion of the nanosheet layer 114 or other silicon containing layers under the sidewall spacers.

FIG. 1AF and FIG. 1AG, shows cross sections of the nanosheet transistor 101 after a first level of interconnects 153 is complete. A metal silicide layer (not specifically shown) may be formed on the source region 132, the drain region 133, the back gate region 160 (out of the plane of the cross section, referred to in FIG. 1A) and exposed portions of the gate conductor 142. The metal silicide layer may provide ohmic electrical connections to the source region 132, the drain region 133, the back gate region 160 and the gate conductor 142 with lower resistances compared to a similar microelectronic device without metal silicide layer.

A pre-metal dielectric (PMD) layer 151 is formed over the top surface 107 of the substrate 104. The PMD layer 151 may include one or more dielectric layers, such as silicon nitride, silicon oxynitride, and silicon dioxide. In some examples, the PMD layer 151 includes a PMD liner and a main dielectric sublayer formed on the PMD liner. Subsequently, the PMD layer 151 may be planarized by a CMP process (not specifically shown). Contacts 152, e.g. Tungsten plugs, are formed within the PMD layer 151 to provide electric connection to the source region 132 and the drain region 133, the back gate region 160, and the gate conductor 142 (out of the plane of FIG. AF). Interconnects 153, electrically connected to the contacts 152, are formed over the PMD layer 151 using any suitable metallization scheme and provide electrical contact between the nanosheet transistor 101 and other components of the microelectronic device 100.

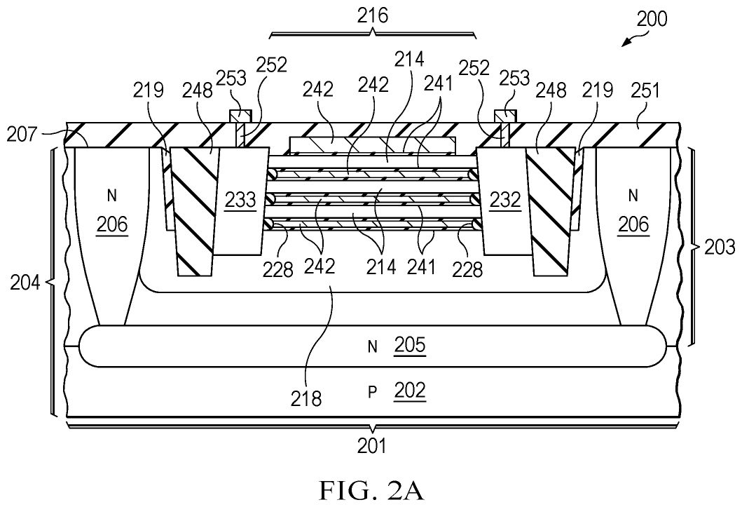

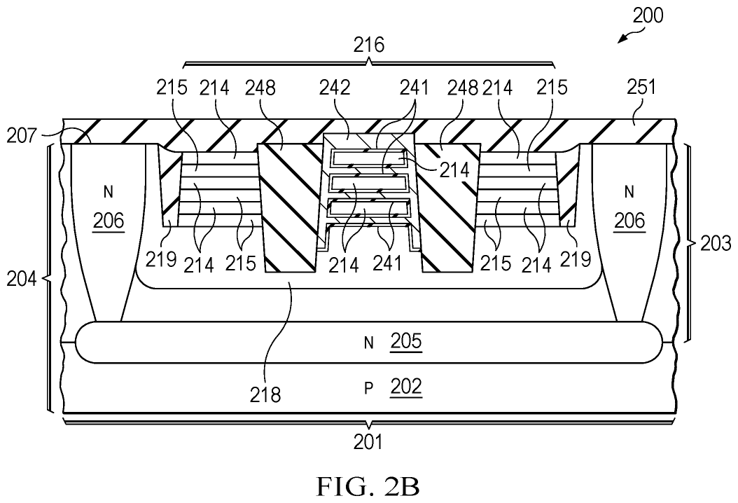

FIG. 2A and FIG. 2B, shows cross sections of a microelectronic device 200 containing a nanosheet n-type metal oxide semiconductor (NMOS) transistor 201 after formation. The nanosheet NMOS transistor 201 is formed on a base wafer 202. On the base wafer 202, an epitaxial layer 203 is formed, the base wafer 202 and the epitaxial layer 203 forming a substrate 204 with a top surface 207. A PMD 251, contacts 252, and interconnects 253 are formed on the top surface 207. A deep well 206 surrounds the nanosheet NMOS transistor 201 and contacts a buried layer 205. A portion of a dielectric layer 219 remains after the formation of the nanosheet superlattice 216. A portion of the silicon-germanium 215 from the nanosheet superlattice 216 as deposited can be seen in FIG. 2B, but is not a functional portion of the nanosheet NMOS transistor 201. STI 248, surrounds the nanosheet NMOS transistor 201 providing isolation and removing possible parasitic pathways from the nanosheet superlattice 216 between the STI 248 and the dielectric layer 219. The nanosheet NMOS transistor 201 is formed in a p-type well region 218 using similar formation conditions to the p-type well region 118 referred to in FIG. 1F. The nanosheet NMOS transistor 201 includes an n-type source region 232, a n-type drain region 233, silicon nanosheet layers 214, a silicon nanosheet gate dielectric layer 241, and a gate conductor 242. An inner spacer dielectric 228 and the silicon nanosheet gate dielectric layer 241 electrically isolate the gate conductor 242 from the silicon nanosheet layers 214. Additionally, a lightly doped drain (LDD) (not specifically shown) may be formed using conditions similar to those used to form the n-type buffer region 126 referred to in FIG. 1L Unless otherwise indicated, the components of the nanosheet NMOS transistor 201 may be formed using conditions similar to those used to form the corresponding components of the nanosheet transistor 101 described in FIG. 1A through FIG. 1AG.

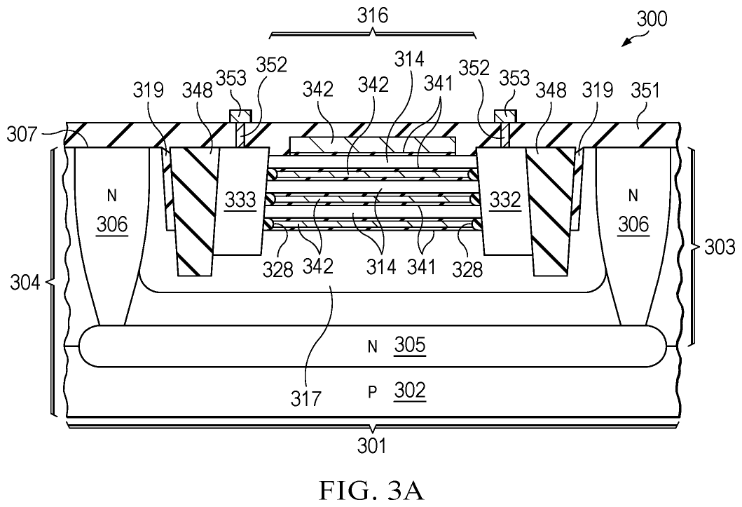

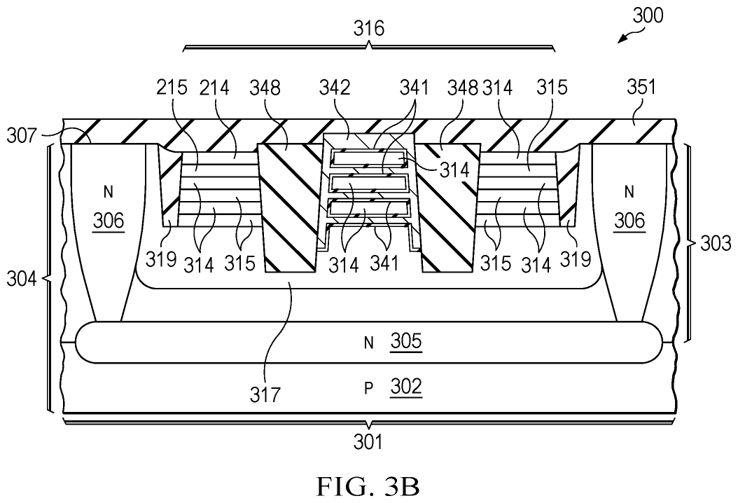

FIG. 3A and FIG. 3B, shows cross sections of a microelectronic device 300 containing a nanosheet p-type metal oxide semiconductor (PMOS) transistor 301 after formation. The nanosheet PMOS transistor 301 is formed on a base wafer 302. On the base wafer 302, an epitaxial layer 303 is formed, the base wafer 302 and the epitaxial layer 303 forming a substrate 304 with a top surface 307. A PMD 351, contacts 352, and interconnects 353 are formed on the top surface 307. A deep well 306 surrounds the nanosheet PMOS transistor 301 and contacts a buried layer 305. A portion of the dielectric layer 319 remains after the formation of the nanosheet PMOS transistor 301. A portion of the silicon-germanium 315 from the as deposited nanosheet superlattice 316 can be seen in FIG. 3B, but is not a portion of the functional nanosheet PMOS transistor 301. STI 348, surrounds the nanosheet PMOS transistor 301 providing isolation and removing possible parasitic pathways from the nanosheet superlattice 316 between the STI 348 and the dielectric layer 319. The nanosheet PMOS transistor 301 is formed in an n-drift region 317 using similar formation conditions to the n-drift region 117 referred to in FIG. 1F. An optional n-type well region (not specifically shown) may also be formed in the n-drift region 317. The nanosheet PMOS transistor 301 includes a p-type source region 332, a p-type drain region 333, silicon nanosheet layers 314, a silicon nanosheet gate dielectric layer 341, and a gate conductor 342. An inner spacer dielectric 328 and the silicon nanosheet gate dielectric layer 341 electrically isolate the gate conductor 342 from the silicon nanosheet layers 314. Additionally, a lightly doped drain (LDD) (not specifically shown) may be formed using conditions similar to those used to form the p-type body region 125 referred to in FIG. 1L. Unless otherwise indicated, the components of the nanosheet PMOS transistor 301 may be formed using conditions similar to those used to form of the corresponding components of the nanosheet transistor 101 described in FIG. 1A through FIG. 1AG.

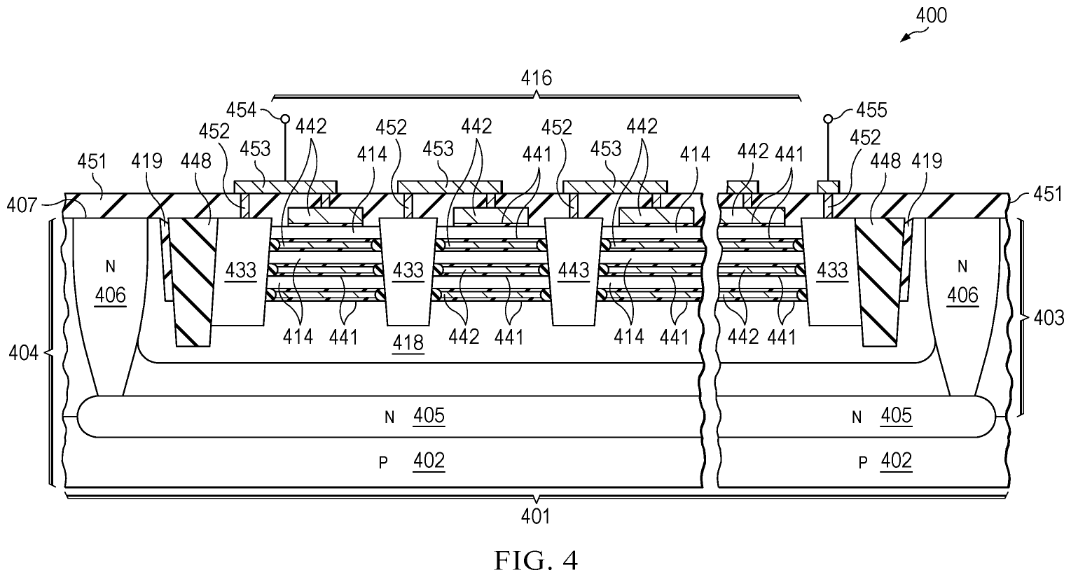

Referring to FIG. 4, a cross section of a nanosheet resistor 401 is shown. The nanosheet resistor 401 may provide a convenient resistor component for a microelectronic device 100 containing other nanosheet components such as the nanosheet transistor 101. The nanosheet resistor 401 is formed on a base wafer 402. On the base wafer 402, an epitaxial layer 403 is formed, the base wafer 402 and the epitaxial layer 403 forming a substrate 404 with a top surface 407. A PMD 451, contacts 452, and interconnects 453 are formed on the top surface 407. A deep well 406 surrounds the nanosheet resistor 401 and contacts a buried layer 405. A portion of a dielectric layer 419 remains after the formation of the nanosheet superlattice 416. STI 448, surrounds the nanosheet resistor 401 providing isolation and removing parasitic pathways from the nanosheet superlattice 416 between the STI 448 and the dielectric layer 419. The nanosheet resistor 401 includes a nanosheet superlattice 416, silicon nanosheet layers 414-1, 414-2, 414-3 . . . 414-X, collectively silicon nanosheet layers 414, a silicon nanosheet gate dielectric layer 441, and a gate conductor 442 into which a plurality of n-type drain regions 433-1, 433-2, 433-3 . . . 433-X, collectively n-type drain regions 433, have been formed. A n-drift region 418 at least partially surrounds the components of the nanosheet resistor 401. An inner spacer dielectric 428 and the silicon nanosheet gate dielectric layer 441 electrically isolate the gate conductor 442 from the silicon nanosheet layers 414. The nanosheet resistor 401 has a first terminal 454 and a second terminal 455. In the example nanosheet resistor 401 current enters through first terminal 454 into the n-type drain region 433-1. Current then flows from the n-type drain region 433-1 into the silicon nanosheet layers 414-1 and flows into the n-type drain region 433-2. The current path is repeated through the plurality of n-type drain regions 433 and silicon nanosheet layers 414 until the current reaches the n-type drain region 433-X, from which the current exits the nanosheet resistor 401 through the n-type drain region 433-X through a contact 452 and an interconnect 453 to the second terminal 455.

The overall resistance of the nanosheet resistor 401 may be controlled by modifying the number of the plurality of n-type drain regions 433 and the length of the nanosheet superlattice 416. The resistance of the nanosheet resistor 401 can also be modified by modifying the n-drift region 418 dose, or by adding n-type buffer regions (not specifically shown) around the plurality of n-type drain regions 433, the n-type buffer regions being similar to the n-type buffer region 126 referred to in FIG. 1L. The electrical connection between each of the plurality of n-type drain regions 433 to the gate conductor 442 through contacts 432 and an interconnect 453 may reduce any field effects. The components of the nanosheet resistor 401 may be formed using conditions similar to those used to form the corresponding components of the nanosheet transistor 101 described in FIG. 1A through FIG. 1AG.

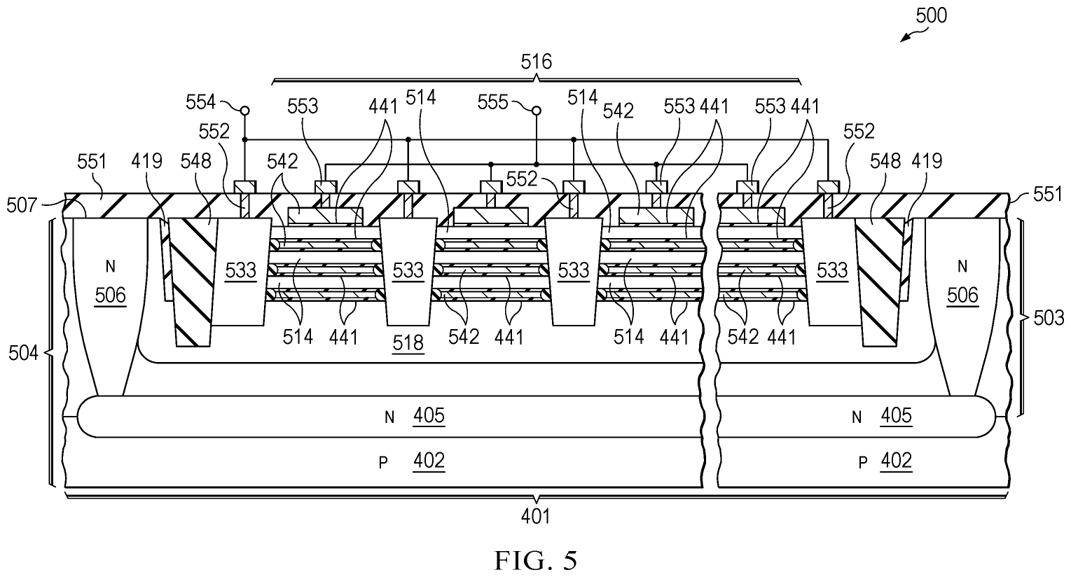

Referring to FIG. 5, a cross section of a nanosheet metal oxide capacitor (MOSCAP) 501 is shown. The nanosheet MOSCAP 501 may provide convenient capacitor component for a microelectronic device 100 containing other nanosheet components such as the nanosheet transistor 101. The nanosheet MOSCAP 501 is formed on a base wafer 502. On the base wafer 502, an epitaxial layer 503 is formed, the base wafer 502 and the epitaxial layer 503 forming a substrate 504 with a top surface 507. A PMD 551, contacts 552, and interconnects 553 are formed on the top surface 507. A deep well 506 surrounds the nanosheet MOSCAP 501 and contacts a buried layer 505. A portion of a dielectric layer 519 remains after the formation of the nanosheet superlattice 516. STI 548, surrounds the nanosheet MOSCAP 501 providing isolation and removing parasitic resistance pathways from the nanosheet superlattice 516 between the STI 548 and the dielectric layer 519.

The nanosheet MOSCAP 501 includes a nanosheet superlattice 516, silicon nanosheet layers 514-1, 514-2, 514-3 . . . 514-X, collectively silicon nanosheet layers 514, a silicon nanosheet gate dielectric layer 541, and a gate conductor 542 into which a plurality of n-type drain regions 533-1, 533-2, 533-3 . . . 533-X, collectively n-type drain regions 533, have been formed. A n-drift region 518 at least partially surrounds the components of the nanosheet MOSCAP 501. An inner spacer dielectric 528 and the silicon nanosheet gate dielectric layer 541 electrically isolate the gate conductor 542 from the nanosheet silicon 514. The nanosheet MOSCAP 501 has a first terminal 554 and a second terminal 455. The example MOSCAP 501 may also be made with the opposite conductivity types of those described by changing n-type regions of the MOSCAP 501 to p-type regions.

In the example nanosheet MOSCAP 501 The first terminal 554 is electrically connected in parallel to each of the plurality of n-type drain regions 533 through interconnects 553 and contacts 552. The second terminal 555 of the nanosheet MOSCAP 501 is connected to the gate conductor 542 through interconnects 553 and contacts 552. The plurality of n-type drain regions 533 connected to the first terminal 554 and the gate conductor 542 connected to the second terminal 555 are electrically isolated from each other by the silicon nanosheet gate dielectric layer 541 and the inner spacer dielectric 528, and form the components of the nanosheet MOSCAP 501. The components of the nanosheet MOSCAP 501 may be formed using formation conditions similar to those used to form the corresponding components of the nanosheet transistor 101 described in FIG. 1A through FIG. 1AG.

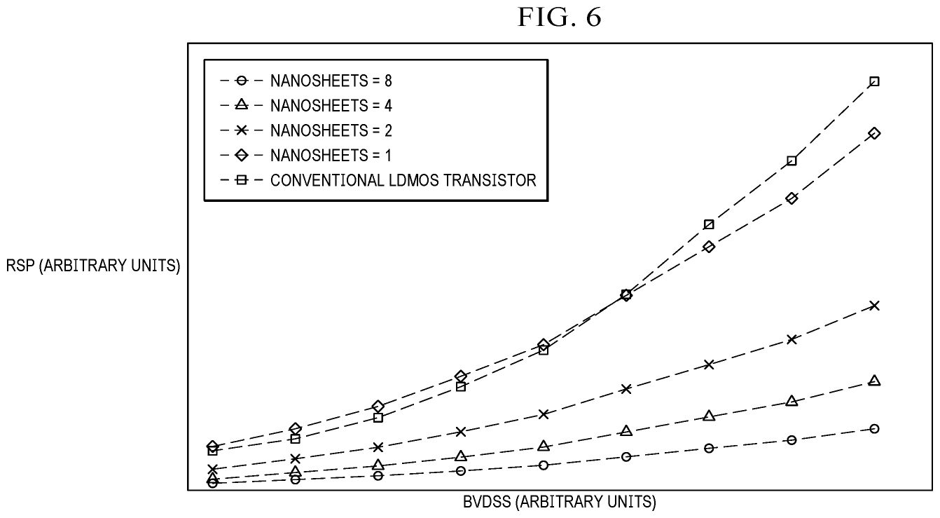

FIG. 6 is a graph of a simulation comparing the on-state resistance (Rsp) and the on-stage break down voltage (BVDSS) of nanosheet transistors 101 with varying numbers of nanosheet layers 114. The graph also includes the Rsp vs. BVDSS for a traditional LDMOS transistor. As shown in the graph of FIG. 6, the Rsp vs. BVDSS of a nanosheet transistor 101 with a single nanosheet layer 114 and a traditional LDMOS transistor are comparable. As the number of nanosheet layers 114 of the nanosheet transistor 101 increases from 2 to 4 to 8, a trend is shown, whereby an increased number of nanosheets in a given nanosheet transistor 101 results in a lower Rsp for a given BVDSS. The lower Rsp at a given BVDSS is advantageous for LDMOS nanosheet transistors 101 with respect to cost and performance as LDMOS geometries shrink.

While various examples of the present disclosure have been described above, it should be understood that they have been presented by way of example and not limitation. As such, although foregoing examples are described to use various resist layers (e.g., Photoresist or photomask layers) to perform various process steps (e.g., Implant steps or etch steps), the present disclosure is not limited thereto. For example, one or more hard masks (including one or more layers) may be patterned to define various regions for subsequent process steps to be applied (e.g., Regions for receiving dopant atoms, regions to block etchants). Moreover, the resist layers may include multi-level resists instead of a single-level resist in some examples. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and equivalents.

What is claimed is:

1. A microelectronic device, comprising:
a source region and a drain region having a first conductivity type extending below a top surface of a semiconductor substrate having an opposite second conductivity type;
first and second semiconductor nanosheet layers contacting the source region and the drain region;
a first gate dielectric layer on the first semiconductor nanosheet layer and a second gate dielectric layer on the second semiconductor nanosheet layer; and
a gate conductor contacting the first and second gate dielectric layers.

2. The microelectronic device as recited in claim 1, further comprising a drain drift region of the first conductivity type extending towards the source region, wherein the drain region, a portion of the semiconductor substrate, and a portion of the first and second semiconductor nanosheet layers are in the drain drift region, the drain drift region having an average dopant concentration less than the average dopant concentration of the drain region.

3. The microelectronic device as recited in claim 1, further comprising a well region of the second conductivity type extending towards the drain region, the source region, a portion of the semiconductor substrate, and a portion of the first and second semiconductor nanosheet layers being in the well region.

4. The microelectronic device as recited in claim 1, further comprising a body region of the second conductivity type surrounding the source region and a portion of the first and second semiconductor nanosheet layers nearest the source region, the body region being in a well region.

5. The microelectronic device as recited in claim 1, further comprising a buffer region of the first conductivity type surrounding the drain region and a portion of the first and second semiconductor nanosheet layers nearest the source region, the buffer region being in a drain drift region.

6. The microelectronic device as recited in claim 1, further comprising a gate trench in the first and second semiconductor nanosheet layers, the gate trench extending into the semiconductor substrate, the gate trench being between the source region and the drain region.

7. The microelectronic device as recited in claim 1, further comprising an inner spacer of a dielectric material between a portion of the first and second semiconductor nanosheet layers, the inner spacer electrically isolating a gate conductor from the source region and the drain region.

8. The microelectronic device recited in claim 1, further comprising the first and second semiconductor nanosheet layers of a thickness is greater than 10 nanometers.

9. The microelectronic device as recited in claim 1, further comprising a dielectric filled trench, the dielectric filled trench electrically isolating the first and second semiconductor nanosheet layers, the source region, and the drain region from an adjacent semiconductor superlattice stack.

10. The microelectronic device as recited in claim 1, wherein the first and second nanosheet layers include unalloyed silicon and a sacrificial layer includes a silicon-germanium alloy.

11. A method of forming a microelectronic device, comprising:
forming a trench in a semiconductor substrate having a first conductivity type;
forming a semiconductor stack in the trench, including a sacrificial layer between first and second semiconductor layers; and
forming a source region and a drain region having an opposite second conductivity type extending into the semiconductor stack;
removing the sacrificial layer between the first and second semiconductor layers between the source region and the drain region;
forming a first gate dielectric layer on the first semiconductor layer and a second gate dielectric layer on the second semiconductor layer; and
forming a gate conductor between the first and second gate dielectric layers.

12. The method of claim 11, wherein forming the source and drain regions includes forming a source trench and a drain trench extending into the semiconductor stack, and further comprising forming a recess in the sacrificial layer at sidewalls of the source trench and the drain trench, and filling the recess with an inner spacer, the inner spacer electrically isolating the gate conductor from the source region and the drain region.

13. The method of claim 11, wherein forming the drain region includes forming a drain trench extending into the semiconductor stack, and further comprising forming a buffer region of the second conductivity type along a sidewall of the drain trench.

14. The method of claim 11, further comprising forming a drift region of the second conductivity type in the semiconductor stack and the semiconductor substrate, the drift region surrounding a buffer region and the drain region.

15. The method of claim 11, further comprising forming a body region of the first conductivity type in the semiconductor stack, the body region surrounding the source region.

16. The method of claim 11, further comprising forming a well region of the first conductivity type in the semiconductor stack and the semiconductor substrate, the well region surrounding a body region and the source region.

17. The method of claim 11, further comprising forming a gate trench in the semiconductor stack, the gate trench being between the source region and the drain region, the gate trench contacting a drift region and a well region.

18. The method of claim 11, further comprising forming a superlattice fill region, the superlattice fill region filling gaps between the semiconductor substrate and the semiconductor stack.

19. The method of claim 11, wherein the first and second semiconductor layers have a thickness greater than 30 nm.

20. The method of claim 11, further comprising forming a dielectric layer on a sidewall of the trench.

21. The method of claim 11, wherein a first and second nanosheet layers include unalloyed silicon and the sacrificial layer includes a silicon-germanium alloy.

22. The method of claim 11, wherein the sacrificial layer includes a dielectric material.
